(19) United States
(12) Patent Application Publication
(10) Pub. No.: US 2026/0202864 A1
(43) Pub. Date: Jul. 16, 2026

(54) PASSIVE PRESSURE AMPLIFICATION DEVICE

(71) Applicant: POLYTECH FORGE LLC, Port Charlotte, FL (US)

(72) Inventor: Jacob FRIEND, Brattleboro, VT (US)

(73) Assignee: POLYTECH FORGE LLC, Port Charlotte, FL (US)

(21) Appl. No.: 19/450,159

(22) Filed: Jan. 15, 2026

Related U.S. Application Data
(60) Provisional application No. 63/746,248, filed on Jan. 16, 2025.
(60) Provisional application No. 63/746,246, filed on Jan. 16, 2025.

(51) Int. Cl. G05D 16/04; F16K 15/18; F16K 17/10; G05D 16/06

(52) U.S. Cl. CPC G05D 16/0402; F16K 15/1843; F16K 17/10; G05D 16/0608

(57) ABSTRACT

A passive pressure amplification device. The pressure amplification device includes a main body defining an internal chamber extending along a longitudinal axis between an upstream end and a downstream end, the internal chamber being in communication with an external environment at both ends. The internal chamber includes at least one step at which a diameter of the internal chamber decreases, subdividing the internal chamber into at least two subchambers having different effective volumes. A valve body is disposed at the step and separates the subchambers, the valve body defining a passage connecting the subchambers. A check valve arrangement cooperates with the valve body and is configured to permit gas flow from an upstream subchamber to a downstream subchamber only when pressure within the upstream subchamber exceeds a predetermined threshold. Pressure amplification is achieved passively by transfer and confinement of gas within subchambers of decreasing effective volume, without driven compression elements.

### CROSS-REFERENCE TO RELATED APPLICATIONS

This application claims priority to U.S. Provisional Application 63/746,248, filed Jan. 16, 2025, and U.S. Provisional Application 63/746,246, filed Jan. 16, 2025, the entire contents of each of which are hereby incorporated by reference.

### BACKGROUND

Many industrial, and scientific applications, as well as certain consumer products require the application of ultra-high pressures. However, known ultra-high-pressure delivery systems are typically complex and expensive, while also not being adaptable to existing low- and high-pressure delivery systems. Accordingly, an efficient, reliable, and cost-effective solution is desired.

### SUMMARY

According to at least one exemplary embodiment, a passive pressure amplification device is provided. The device may include a main body having an internal chamber extending from an upstream end to a downstream end and being in communication with at least one environment external to the main body at the upstream end and at the downstream end. The internal chamber may include at least one step at which a diameter of the internal chamber decreases, thereby subdividing the internal chamber into at least two subchambers. A downstream subchamber may have an effective volume less than an effective volume of an immediately upstream subchamber. A valve body may be disposed at the step and may separate the two subchambers. The valve body may define a bore or passage connecting the subchambers. A check valve arrangement may cooperate with the valve body and may be configured to permit gas flow from the upstream subchamber to the downstream subchamber only when pressure within the upstream subchamber exceeds a predetermined threshold.

The passive pressure amplification device may include a plurality of steps, valve bodies, and check valve arrangements arranged in series, such that gas is transferred sequentially through subchambers of decreasing effective volume to achieve passive pressure amplification without mechanically driven compression elements.

According to at least one exemplary embodiment, a passive pressure amplification device includes a main body defining an internal chamber extending between an upstream end and a downstream end and being in communication with an external environment at both ends. The internal chamber may include at least one pressure stepping stage. Each pressure stepping stage may include an upstream subchamber and a downstream subchamber having a smaller effective volume than the upstream subchamber. A valve body may be disposed between and may separate the upstream subchamber and the downstream subchamber. The valve body may define a passage connecting the subchambers. A pressure-responsive valve element may cooperate with the valve body and may be configured to permit gas flow from the upstream subchamber to the downstream subchamber when pressure within the upstream subchamber exceeds a predetermined threshold.

The passive pressure amplification device may include a plurality of pressure stepping stages arranged within the internal chamber, such that pressure amplification is achieved through sequential transfer and confinement of gas within downstream subchambers of decreasing effective volume.

According to at least one exemplary embodiment, a method of designing a passive pressure amplification device is provided. The method may include determining a desired outlet pressure relative to an inlet pressure and selecting at least one pressure stepping stage comprising an upstream subchamber and a downstream subchamber separated by a valve body and a pressure-responsive valve element. The method may further include selecting a target stage pressure ratio or an effective volume ratio between the upstream subchamber and the downstream subchamber, and determining effective subchamber volumes such that the downstream subchamber has a smaller effective volume than the upstream subchamber. The method may further include configuring the valve body and the pressure-responsive valve element such that gas is transferred between subchambers only when a predetermined pressure threshold is exceeded. The method may further include selecting a plurality of pressure stepping stages arranged in series to achieve a desired cumulative pressure amplification.

### BRIEF DESCRIPTION OF THE FIGURES

Advantages of embodiments of the present invention will be apparent from the following detailed description of the exemplary embodiments. The following detailed description should be considered in conjunction with the accompanying figures in which:

FIG. 1 is a perspective view of an exemplary embodiment of a passive pressure amplification device.

FIG. 2A is an elevational view of the exemplary embodiment of a passive pressure amplification device.

FIG. 2B is a cross-sectional view of the exemplary embodiment of a passive pressure amplification device, along line A-A of FIG. 2.

FIG. 2C shows the cross-sectional view of FIG. 2B, with the couplings and check valve arrangements removed for clarity.

FIG. 2D is a cross-sectional view of the main body of the exemplary embodiment of a passive pressure amplification device, along line A-A of FIG. 2.

FIG. 3 is an exploded view of the exemplary embodiment of a passive pressure amplification device.

FIG. 4A is an elevational view of a first valve body of the exemplary embodiment of a passive pressure amplification device.

FIG. 4B is a cross-sectional view of the first valve body along line B-B of FIG. 4A.

FIG. 5A is an elevational view of a second valve body of the exemplary embodiment of a passive pressure amplification device.

FIG. 5B is a cross-sectional view of the second valve body along line C-C of FIG. 5A.

FIG. 6A is an elevational view of a third valve body of the exemplary embodiment of a passive pressure amplification device.

FIG. 6B is a cross-sectional view of the third valve body along line D-D of FIG. 6A.

FIG. 7A is an elevational view of a fourth valve body of the exemplary embodiment of a passive pressure amplification device.

FIG. 7B is a cross-sectional view of the fourth valve body along line E-E of FIG. 7A.

FIG. 8A is an elevational view of a fifth valve body of the exemplary embodiment of a passive pressure amplification device.

FIG. 8B is a cross-sectional view of the fifth valve body along line F-F of FIG. 8A.

### DETAILED DESCRIPTION

Aspects of the invention are disclosed in the following description and related drawings directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiment are not necessarily to be construed as preferred or advantageous over other embodiments. Moreover, the terms “embodiments of the invention”, “embodiments” or “invention” do not require that all embodiments of the invention include the discussed feature, advantage or mode of operation.

According to at least one exemplary embodiment, an inline, passive pressure amplification device is disclosed. The passive pressure amplification device may be configured to increase gas pressure in a staged manner using a plurality of chambers having differing effective volumes and a plurality of pressure-responsive valve elements disposed therebetween. The passive pressure amplification device may operate without pistons or mechanically driven compression members, instead relying on controlled transfer and confinement of gas between chambers of progressively decreasing volume.

The passive pressure amplification device may be optimized for amplifying, to high pressure levels, input gas pressure from devices providing intermittent gas flow; for example, devices such a standard shop compressor, portable air compressor, hand pump, or other low pressure air source. The passive pressure amplification device may be compact, efficient, and reliable, making it suitable for a variety of industrial and scientific applications. The high-pressure inline passive pressure amplification device may operate by compressing air through a series of chambers, with each chamber having a reduced volume than the prior upstream chamber, thereby increasing the pressure of the air. A series of valve bodies directs airflow between the chambers while a series of associated check valves prevents backflow. The system can provide stepwise pressure amplification, ultimately delivering air at extremely high pressures. Accordingly, embodiments of the passive pressure amplification device can provide a work reduction system that increases a possible pressure output range of a compression source.

According to at least one exemplary embodiment, the passive pressure amplification device may include at least one pressure stepping stage, or a plurality of pressure stepping stages. Each pressure stepping stage may include an upstream chamber and a downstream chamber separated by a pressure-responsive check valve arrangement. When gas is transferred from the upstream chamber into the downstream chamber and the downstream chamber is subsequently sealed, the pressure of the gas within the downstream chamber may increase as a function of the relative volumes of the two chambers.

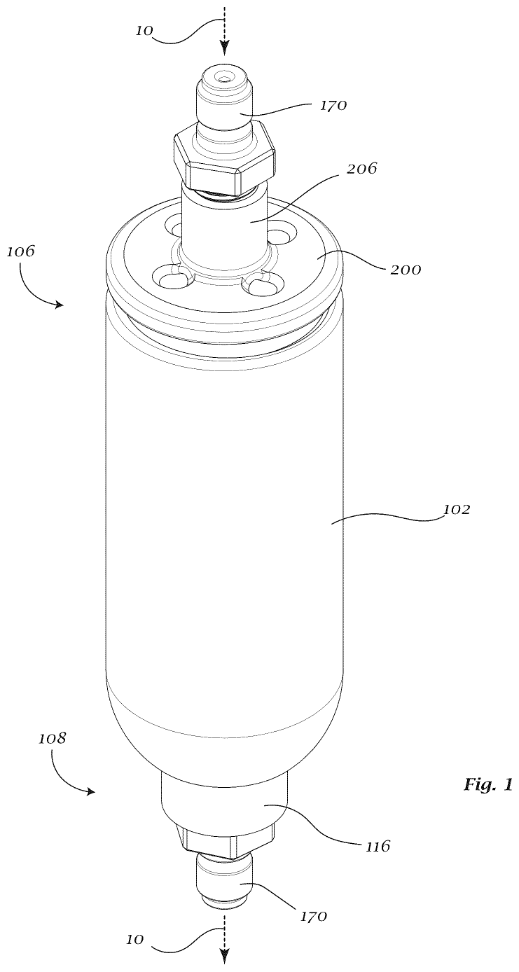

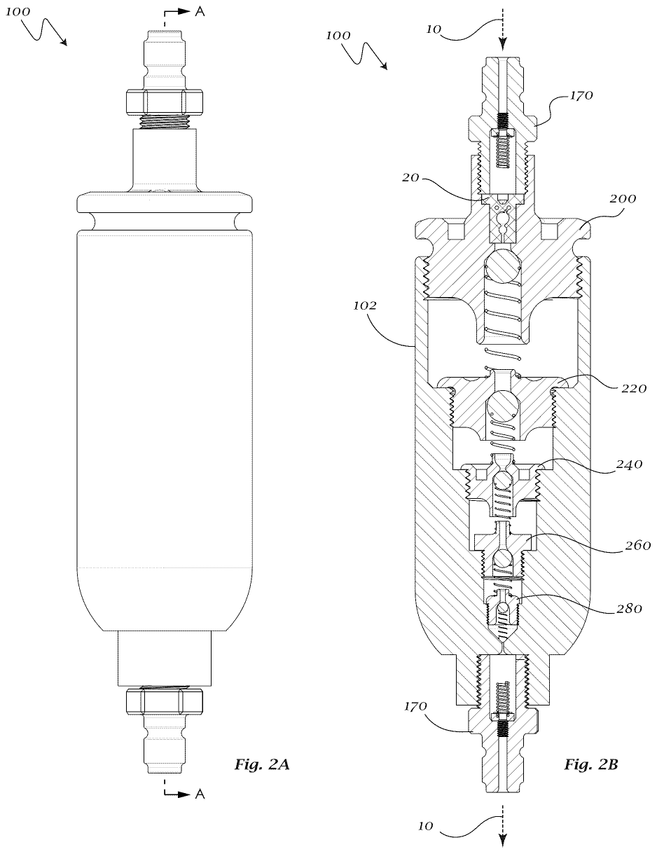

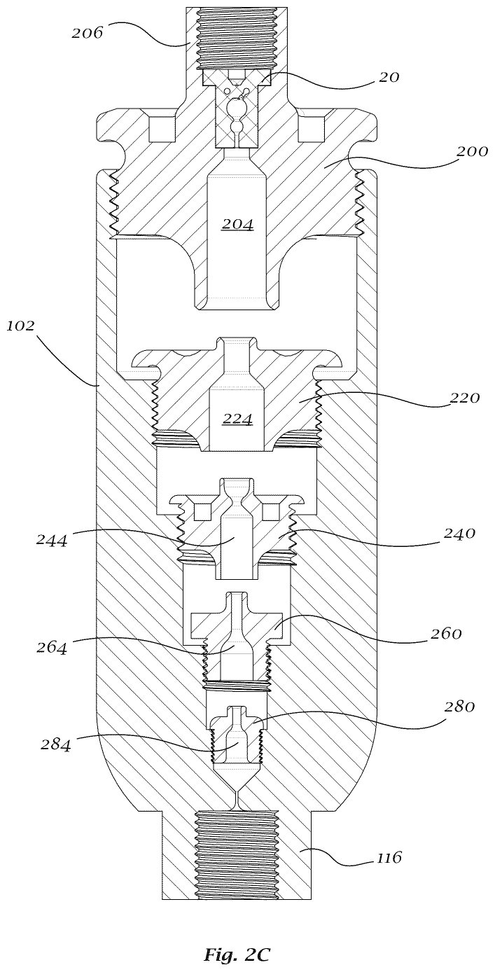

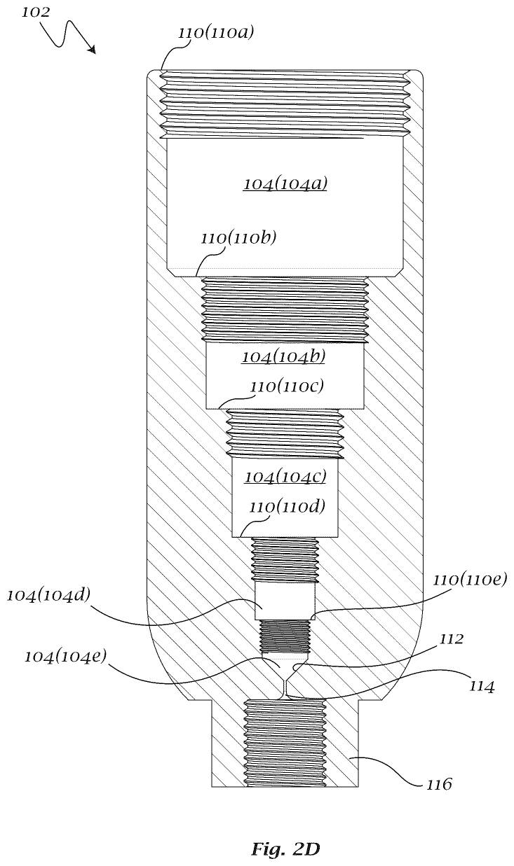

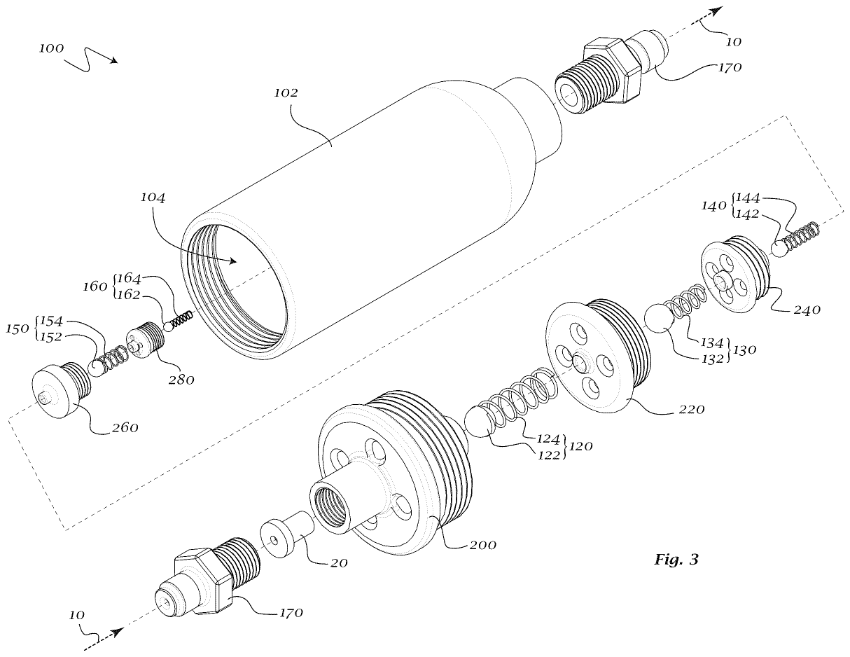

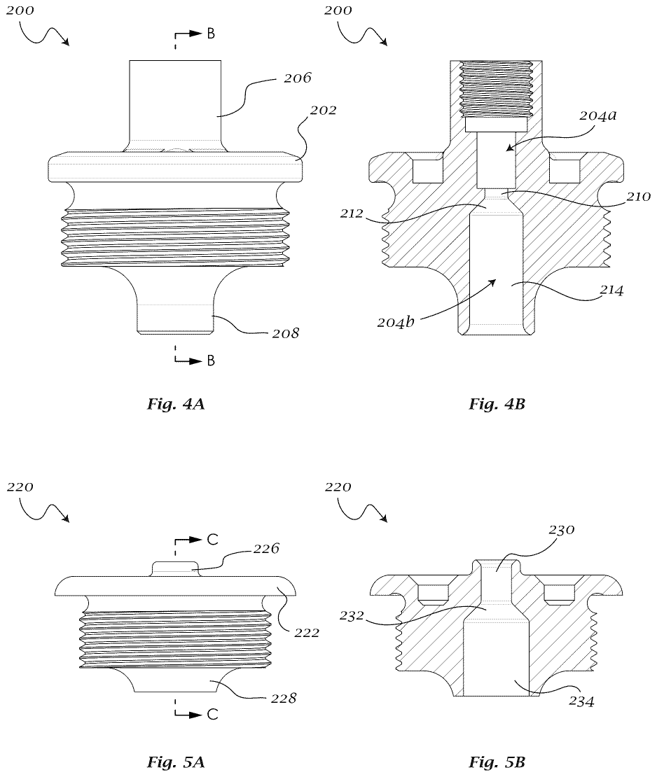

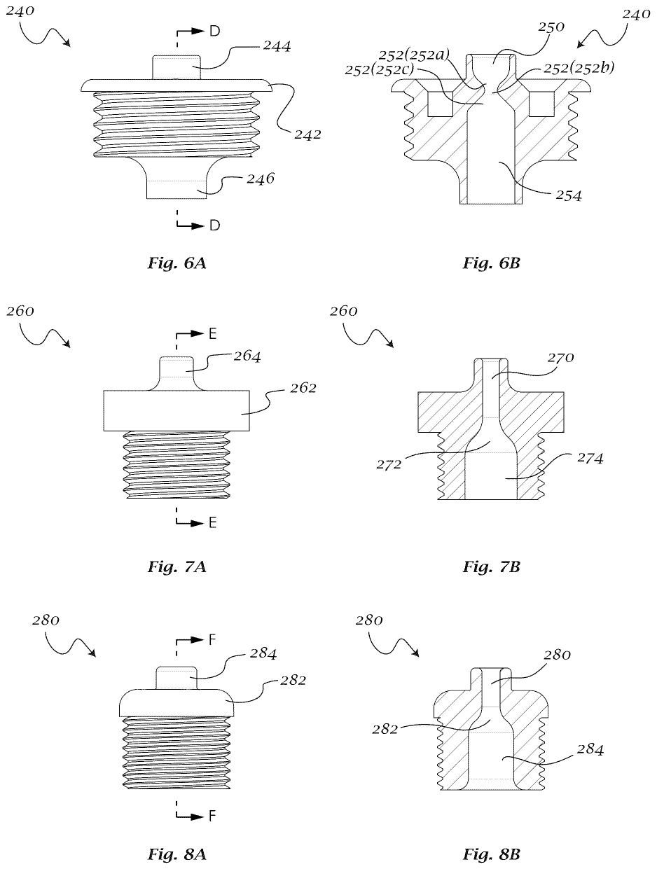

According to at least one exemplary embodiment, and with reference to FIGS. 1-8, a passive pressure amplification device 100 is disclosed. Passive pressure amplification device 100 can include a main body 102 having an internal chamber 104 defined therein, inside which may be disposed at least one valve body and at least one check valve arrangement. The internal chamber may be coaxial with the longitudinal axis of body 102.

Internal chamber 104 may be open to the exterior at a upstream end 106 of main body 102 and at a downstream end 108 of main body 102, the diameter of the upstream end being greater than the diameter of the downstream end. Furthermore, proximate downstream end 108, internal chamber 104 may communicate with the exterior via a narrow-diameter passage 114. Both upstream end 106 and downstream end 108 may include threaded portions to couple to corresponding components, as further discussed below.

In operation, air may pass through the internal chamber along airflow path 10, from upstream end 106 towards downstream end 108. As used herein, terms of spatial relation between the various components of pressure amplification device 100, as well as the terms “upstream” and “downstream” should be understood as being discussed with respect to the direction of airflow path 10.

In an exemplary embodiment, internal chamber 104 may have at least one step 110 defined along the length thereof, with the diameter of the internal chamber decreasing in a stepwise manner at the at least one step. Internal chamber 104 may therefore be subdivided into at least two subchambers, with the downstream subchamber having a lesser volume than the upstream subchamber. In another exemplary embodiment, internal chamber 104 may have a plurality of steps defined along the length thereof, with the volume of the internal chamber decreasing in a stepwise manner at each step of the plurality of steps. Internal chamber 104 may therefore be subdivided into a plurality of subchambers, with each downstream subchamber having a lesser volume than the upstream subchambers. In exemplary embodiments, a portion of the surrounding wall of each subchamber may be provided with threading so as to engage and secure a corresponding valve body within the subchamber.

In the exemplary embodiment illustrated in FIGS. 1-8, internal chamber 104 may have five steps 110a, 110b, 110c, 110d, 110e defined along the length thereof, with the volume of internal chamber 104 decreasing in a stepwise manner at each step. It should be appreciated that, as used herein, the rim surrounding the opening of internal chamber 104 at upstream end 106 is considered a step. The internal chamber may therefore be subdivided into a plurality of subchambers 104a, 104b, 104c, 104d, 104e, with the volumes of the subchambers decreasing in the direction of airflow 10. All subchambers may be arranged coaxially along the longitudinal axis of body 102.

Body 102 may include a coupling adaptor 116 disposed at downstream end 108. Coupling adaptor 116 may be sized and shaped to receive a coupling 170 therein, and may include threaded portions to couple to complementary threaded portions of the coupling. In some exemplary embodiments, the coupling may be a standard foster fitting with an internal check valve mechanism. When the coupling is attached to body 102, the furthest-downstream subchamber (e.g., subchamber 104e in the illustrated embodiment) of internal chamber 104 may be in communication with an internal bore of the coupling via narrow-diameter passage 114. It should be appreciated that any type of coupling that enables pressure amplification device 100 to function as described herein may be contemplated and provided as desired.

Pressure amplification device 100 may include at least one valve body disposed within internal chamber 104. At upstream end 106, internal chamber 104 may be open to the exterior via a substantially large-diameter opening, sized and shaped to receive a valve body therein, the valve body being disposed between the first upstream subchamber (e.g., subchamber 104a in the illustrated embodiment) of internal chamber 104 and the exterior. Furthermore, an additional, internal valve body may be disposed at each step of internal chamber 106. Accordingly, the number of valve bodies may correspond to the number of steps 110 defined in internal chamber 104, with each internal valve body being disposed between two adjacent subchambers of internal chamber 104.

In the exemplary embodiment illustrated in FIGS. 1-8, passive pressure amplification device 100 may include valve bodies 200, 220, 240, 260, 208 disposed at steps 110a, 110b, 110c, 110d, 110e, respectively, with the diameters of the valve bodies decreasing in the direction of airflow 10. It should be appreciated that, as used herein, the rim surrounding the opening of internal chamber 104a at upstream end 106 is considered a step 110, i.e. step 110a. All valve bodies may be arranged coaxially along the longitudinal axis of body 102.

Disposed between the furthest-downstream valve body (e.g., valve body 280 in the illustrated embodiment) and the narrow-diameter passage 114 may be a check valve arrangement. In exemplary embodiments having more than one valve body, additional check valve arrangements may be disposed between each adjacent pair of valve bodies. In the exemplary embodiment illustrated in FIGS. 1-8, pressure amplification device 100 may include check valve arrangements 120, 130, 140, 150 disposed between valve bodies 220 & 240, 240 & 260, and 260 & 280, respectively, and a check valve arrangement 160 disposed between valve body 280 and narrow-diameter passage 114. In an exemplary embodiment, each check valve arrangement may include ball and spring components. All check valve arrangements may be arranged coaxially along the longitudinal axis of body 102.

The plurality of valve bodies of the exemplary embodiment illustrated in FIGS. 1-8 will now be discussed in the direction of airflow path 105. A first valve body 200 may be disposed within first subchamber 104a, at the open end of chamber 104. First valve body 200 may therefore seal the open end of chamber 104. First valve body 200 may include a flange 202 having a diameter substantially similar to the diameter of body 102, a central bore 204 extending along the longitudinal axis of first valve body 200, a coupling adaptor 206 disposed at an upstream end of first valve body 200, and a tubular extension 208 surrounding bore 204 disposed at a downstream end of first valve body 200.

Central bore 204 may include a first section 204a sized and shaped to receive a thermal regulator 20 therein. Thermal regulator 20 may be a thermal regulator substantially as described in U.S. Provisional Patent Application 63/746,246, the entire contents of which are incorporated herein by reference. The first section 204a for receiving thermal regulator 20 may be disposed proximate to coupling adaptor 206. Central bore 204 may further include a second section 204b having substantially a bottle-like shape. As seen in the direction of the airflow, second section 204b may include a narrow-diameter portion 210 disposed proximate and in communication with the first section, a diverging conical portion 212, and a wide-diameter portion 214 extending towards the downstream end of valve body 200. Central bore 204 may further flare radially outward proximate the downstream opening thereof.

A second valve body 220 may be disposed between first subchamber 104a and second subchamber 104b. Second valve body 220 may include a flange 222 for engaging step 110a of internal chamber 104, a central bore 224 extending along the longitudinal axis of first valve body 220, an upstream tubular extension 226, and a downstream tubular extension 228. Central bore 224 may have substantially a bottle-like shape, and, as seen in the direction of the airflow, may include a narrow-diameter portion 230 disposed proximate an upstream opening into first subchamber 104a, a diverging conical portion 232, and a wide-diameter portion 234 extending towards a downstream end of valve body 220 that opens into second subchamber 104b. Central bore 224 may further flare radially outward proximate the upstream opening thereof.

Disposed between first valve body 200 and second valve body 220 may be first check valve arrangement 120. First check valve arrangement 120 may include a ball 122 and spring 124. A downstream end of spring 124 may abut the upstream surface of second valve body 220 and may be mounted on upstream tubular extension 226. Spring 124 may extend into wide-diameter portion 214 of bore 204 of first valve body 200, and may resiliently bias ball 122 against the conical portion 212 of bore 204.

A third valve body 240 may be disposed between second subchamber 104b and third subchamber 104c. Third valve body 240 may include a flange 242 for engaging step 110b of internal chamber 104, a central bore 244 extending along the longitudinal axis of third valve body 240, an upstream tubular extension 246, and a downstream tubular extension 248. Central bore 244 may have substantially an hourglass shape, and, as seen in the direction of the airflow, may include a first wide-diameter portion 250 disposed proximate an upstream opening into second subchamber 104b, an hourglass portion 252, and a second wide-diameter portion 254 extending towards a downstream end of valve body 240 that opens into third subchamber 104c. Central bore 244 may further flare radially outward proximate the upstream opening thereof. The hourglass portion 252 may be disposed between the two wide diameter portions and, as seen in the direction of the airflow, may include a curved converging portion 252a, a narrow-diameter portion 252b, and a conical diverging portion 252c.

Disposed between second valve body 220 and third valve body 240 may be second check valve arrangement 130. Second check valve arrangement 130 may include a ball 132 and spring 134. A downstream end of spring 134 may abut the upstream surface of third valve body 240 and may be mounted on upstream tubular extension 246. Spring 134 may extend into wide-diameter portion 234 of bore 224 of second valve body 220, and may resiliently bias ball 132 against the conical portion 232 of bore 224.

A fourth valve body 260 may be disposed between third subchamber 104c and fourth subchamber 104d. Fourth valve body 206 may include a flange 262 engaging step 110c of internal chamber 104, a central bore 264 extending along the longitudinal axis of fourth valve body 260, and an upstream tubular extension 266. Central bore 264 may have substantially a bottle-like shape, and, as seen in the direction of the airflow, may include a narrow-diameter portion 270 disposed proximate an upstream opening into third subchamber 104c, a curved diverging portion 272, and a wide-diameter portion 274 extending towards a downstream end of valve body 260 that opens into fourth subchamber 104d. Central bore 264 may further flare radially outward proximate the upstream opening thereof.

Disposed between third valve body 240 and fourth valve body 260 may be third check valve arrangement 140. Third check valve arrangement 140 may include a ball 142 and spring 144. A downstream end of spring 144 may abut the upstream surface of fourth valve body 260 and may be mounted on upstream tubular extension 266. Spring 144 may extend into wide-diameter portion 254 of bore 244 of third valve body 240, and may resiliently bias ball 142 against the conical portion 252 of bore 244.

A fifth valve body 280 may be disposed between fourth subchamber 104d and fifth subchamber 104e. Fifth valve body 280 may include a flange 282 engaging step 110d of internal chamber 104, a central bore 284 extending along the longitudinal axis of fifth valve body 280, and an upstream tubular extension 286. Central bore 284 may have substantially a bottle-like shape, and, as seen in the direction of the airflow, may include a narrow-diameter portion 290 disposed proximate an upstream opening into third subchamber 104d, a curved diverging portion 292, and a wide-diameter portion 294 extending towards a downstream end of valve body 280 that opens into fifth subchamber 104e. Central bore 284 may further flare radially outward proximate the upstream and downstream openings thereof.

Disposed between fourth valve body 260 and fifth valve body 280 may be fourth check valve arrangement 150. Fourth check valve arrangement 150 may include a ball 152 and spring 154. A downstream end of spring 154 may abut the upstream surface of fifth valve body 280 and may be mounted on upstream tubular extension 286. Spring 154 may extend into wide-diameter portion 274 of bore 264 of fourth valve body 260, and may resiliently bias ball 152 against the conical portion 272 of bore 264.

Fifth subchamber 104e may include a converging conical portion 112 that, as seen in the direction of the airflow, narrows towards passage 114. Passage 114 may be a narrow-diameter passage that communicates with the exterior via coupling adaptor 116 and coupling 170. Passage 114 may further flare radially outward proximate the opening to coupling 170.

Disposed between fifth valve body 280 and passage 114 may be fifth check valve arrangement 160. Fifth check valve arrangement 160 may include a ball 162 and spring 164. A downstream end of spring 164 may abut the surface of converging conical portion 112. Spring 164 may extend into wide-diameter portion 294 of bore 284 of fourth valve body 280, and may resiliently bias ball 162 against the conical portion 292 of bore 284.

It should be appreciated that the specific configurations of the bores of each valve body may be selected based on the desired pressure and volume differentials between any adjacentpair of chambers, as well as to provide for the proper functioning of the check valve arrangement at each step. These configurations can then be balanced against the chamber volumes of each step and then in turn against overall size constraints, resulting in a specific shape of the bore. Different design and overall footprint considerations may change the configurations of the bores, all of which may be contemplated and provided as desired.

Coupling adaptors 116, 206, may be sized and shaped to receive couplings 170 therein, and may include threaded portions to couple to complementary threaded portions of the couplings. In an exemplary embodiment, such as the one illustrated in FIGS. 1-8, the couplings may be standard foster fittings. As shown in the drawings, each foster fitting may include a narrow-diameter passage defined therein and in communication with the exterior, an internal check valve mechanism, and a wide-diameter passage defined therein and in communication with internal chamber 104. In some embodiments, couplings 170 may be adapted to quick-couple to other components in a system utilizing pressure amplification device 100. In some exemplary embodiments embodiments, couplings 170 may be any type of coupling that enables pressure amplification device 100 to function as described herein.

Embodiments disclosed herein may provide a multi-stage compression system for efficient pressure amplification, with a compact design suitable for integration into a variety of setups. The embodiments disclosed herein may have a durable construction using high-strength materials and provide a low-maintenance design with easily replaceable components. Furthermore, the embodiments disclosed herein may include integrated safety mechanisms to prevent over-pressurization. Advantages of the embodiments disclosed herein may include efficiency, reliability, scalability, and cost-effectiveness. Stepwise compression can minimize energy loss, while check valves and seals can ensure consistent performance. For scalability, systems can be designed with various pressure capabillities, input requirements, and overall sizes, and the modular design can allow for potential system upgrades. Finally, the embodiments can be designed to work with standard shop air compressors and hand pumps, resulting in a low longterm cost. Non-limiting applications of the disclosed embodiments can include PCP airguns, industrial-grade pneumatic tools, testing and calibration of high-pressure systems, aerospace, automotive, and scientific research equipment requiring high-pressure air supply, and emergency and portable high-pressure systems.

In operation, gas flow may be supplied at upstream end 106 via connector 170 to first valve body 200. In valve body 200, gas may first flow through adiabatic thermal regulator 20, which may increase the temperature of the gas flow to a desired temperature. A thermal regulator may be included if desired, but is not required for the functionality of the pressure amplification device. Inclusion of a thermal regulator may reduce the amount of work necessary to reach a given pressure range in the vessel being filled, as an increased temperature of gas flow would require a lesser volume of gas to reach a desired pressure and therefore would require a lesser about of work. However, the reduction in work is provided at the cost of heating the gas entering the vessel, thereby reducing the effective mass of gas in the vessel due to increased expansion pressures present in the heated chamber.

Subsequently, the gas may flow through narrow-diameter portion 210 of inner bore 204 of valve body 200, up to ball 122 of check valve arrangement 120. The gas pressure may build in narrow-diameter portion 210 until the pressure therein is greater than the pressure in downstream subchamber 104a and the pressure of spring 124, at which point ball 122 may recede so as to allow the high-pressure gas to escape from thermal regulator 20 and narrow-diameter portion 210 into downstream subchamber 104a.

Subsequently, under continued provision of gas to pressure amplification device 100, the gas pressure may build in subchamber 104a such that the gas pressure acts against ball 134 of check valve arrangement 130. The gas pressure may further build in subchamber 104a until the pressure therein is greater than the pressure in downstream subchamber 104b and the pressure of spring 134, at which point ball 132 may recede so as to allow the high-pressure gas to escape from subchamber 104a into downstream subchamber 104b.

Under continued provision of gas to pressure amplification device 100, the above-described process may be repeated at every subsequent downstream subchamber and valve body. As the volume of each downstream subchamber is less than the prior upstream subchamber, the pressure increases at each subsequent downstream subchamber. The pressure achieved after each valve arrangement is directly related to the difference in volume between each subchamber with respect to the upstream subchamber immediately before it, and is also directly related to the volume of the first upstream subchamber with respect to the volume of the final downstream subchamber. The final output pressure capability is therefore dependent on the volumetric ratio between the first upstream subchamber and the final downstream subchamber. By way of example only, if the volume of the first chamber is 500 cc and the volume of the final chamber is lcc, the maximum achievable compression ratio would be 500:1. The feasibility of obtaining the desired ratio in light of available energy capabilities would then depend on the scale of volume reduction between each subchamber in the main body of the pressure amplification device.

In this manner, each subchamber and check valve arrangement may function as a stage that can allow the lower-pressure upstream gas to reach higher pressure in the downstream subchamber, without increasing the effort required by the user at the initial gas source.

It should be appreciated that the output pressure may be adjustable during the design phase of each pressure amplification device by varying the absolute and relative volumes of each subchamber, as well as tuning the spring force of each check valve arrangement for the desired pressure in each subchamber. It should further be appreciated that the quantity of subchambers, valve bodies, and check valve arrangements in embodiments of the passive pressure amplification device may be varied so as to achieve desired operating pressure ranges and energy input requirements.

As a non-limiting example, the illustrated embodiment represents a pressure amplification device that is able to accept up to 100 psi of input pressure. Each stage of pressure amplification device 100 is configured to increase pressure as follows: stage 1 (subchamber 104a): <100 psi; stage 2 (subchamber 104b): ~600 psi; stage 3 (subchamber 104c): −1800 psi; stage 4 (subchamber 104d): ~3600 psi; and stage 5 (subchamber 104e): ~5500 psi. As the number of stages increases, the amount of pressure increase in downstream stages diminishes; for example, in a five-stage system, the upstream stages may provide an increase of 500%-1000% relative to input pressure, while the downstream stages may provide an increase of ~200% relative to the prior upstream stage. The illustrated exemplary embodiment may have a length, including the coupling adapters, of about 13-14 cm, an external diameter of about 3.3-3.4 cm, and an internal diameter at the upstream end of about 3.0-3.1 cm. However, these dimensions are merely intended to provide a general sense of scale and should be understood to be exemplary and non-limiting; the dimensions may be adjusted as desired for the particular application of the thermal regulator.

Furthermore, it should be appreciated that the illustrated embodiment is merely exemplary, and embodiments of the pressure amplification device may be designed to have varying external and internal dimensions, with a varying number of stages, chamber volumes and shapes, and bore volumes and shapes, subject to the design framework discussed in further detail below.

According to at least one exemplary embodiment, a passive pressure amplification device may be designed and dimensioned using an analytical framework relationships referred to herein as the Priest Formula framework. The Priest Formula framework provides a structured approach for configuring a passive, multi-stage pressure amplification device in which pressure amplification is achieved through staged volumetric reduction and controlled valve sequencing. The Priest Formula framework is intended to provide deterministic design relationships for individual compression stages, enable predictable pressure scaling without the use of pistons or mechanically driven compression elements, define activation and stability constraints for staged operation, and support design validation, simulation, and manufacturable implementation. The framework applies to passive, inline pressure amplification devices employing unidirectional valve elements, such as check valves, to enforce staged volumetric pressure stepping.

According to at least one exemplary embodiment, the Priest Formula framework may be applied under a set of assumptions that define its modeling scope. These assumptions may include that the gas behaves as an ideal compressible gas, that each compression stage operates in a quasi-static manner, and that unidirectional flow is enforced by pressure-responsive valve elements. The assumptions may further include that no mechanical work is extracted from the gas, that pressure amplification is achieved exclusively through controlled volume reduction rather than moving compression members, that spring or biasing elements define valve activation thresholds rather than performing compression work, and that thermal effects are excluded from the framework and may be addressed by an independent subsystem or separate analysis. These assumptions are intended to bound the analytical scope of the Priest Formula framework and do not limit practical embodiments from exhibiting additional effects.

According to at least one exemplary embodiment, a single pressure stepping stage of a pressure amplification device may include an upstream chamber and a downstream chamber separated by a pressure-responsive valve element. When gas is transferred from the upstream chamber into the downstream chamber and the downstream chamber is subsequently confined, the pressure within the downstream chamber may increase as a function of the relative effective volumes of the chambers.

In one exemplary approximation, the pressure relationship for a single stage may be expressed as:

$${P}_{i + 1} = {P}_{i} ( \frac{{V}_{i}}{{V}_{i + 1}} ) \qquad ( 1 )$$

where Pᵢ represents a stabilized pressure within upstream chamber i, Vᵢ represents an effective volume of upstream chamber i, and Vᵢ₊₁ represents an effective volume of the downstream chamber. This relationship provides a first-pass approximation for pressure amplification achieved through staged volume reduction.

According to at least one exemplary embodiment, a passive pressure amplification device may include a plurality of pressure stepping stages arranged in series, such that gas pressure is incrementally increased as gas is transferred through successive chambers of decreasing effective volume. In such embodiments, a theoretical maximum output pressure of the pressure amplification device may be approximated as:

$${P}_{o u t} = {P}_{i n} {\prod }_{k = 1}^{N} ( \frac{{V}_{k}}{{V}_{k + 1}} ) \qquad ( 2 )$$

where Pᵢₙ represents an inlet pressure, Pₒᵤₜ represents an outlet pressure, N represents a number of pressure stepping stages, and Vₖ represents effective chamber volume. This expression defines the theoretical maximum output pressure achievable by the system, exclusive of losses.

An effective volume of a chamber may include more than its nominal geometric volume. In one exemplary formulation, effective chamber volume may be expressed as:

$${V}_{i}^{eff} = {V}_{geom , i} + {V}_{dead , i} + {V}_{leak , i} \qquad ( 3 )$$

Where V_{geom,i} represents the geometric chamber volume, V_{dead,i} represents additional volume associated with valve pockets and bores, and V_{leak,i} represents a compliance volume arising from micro-clearances. Effective chamber volume may be selected to decrease monotonically in the downstream direction to ensure pressure amplification.

Each pressure stepping stage may include a pressure-responsive valve element biased by a spring or other biasing mechanism. A valve may open only when an upstream pressure exceeds a downstream pressure by a threshold defined by valve geometry and spring preload. In one exemplary approximation, a valve activation condition may be expressed as:

$${P}_{i} {A}_{seat , i} > {F}_{spring , i} + {P}_{i + 1} {A}_{ball , i} \qquad ( 4 )$$

Assuming A_{ball}≈Aₛₑₐₜ, this condition may be approximated as:

$${P}_{i} > \frac{{F}_{s p r ing , i}}{{A}_{s eat , i}} + {P}_{i + 1} \qquad ( 5 )$$

The spring elements define sequencing, timing, and stability of staged operation rather than contributing compression energy.

Stable operation of the pressure amplification device may be promoted by selecting chamber volume ratios within a bounded range. In one exemplary embodiment, a ratio of effective volumes between adjacent stages may satisfy:

$$1.8 \leq \frac{{V}_{i}}{{V}_{i + 1}} \leq 5.0 \qquad ( 6 )$$

In a preferred engineering range, the ratio may satisfy:

$$2.2 \leq \frac{{V}_{i}}{{V}_{i + 1}} \leq 3.5 \qquad ( 7 )$$

Volume ratios outside these ranges may result in instability, inefficiency, or excessive valve activation thresholds.

Operation of the pressure amplification device may comply with conservation of energy, such that output energy does not exceed input energy. Energy may be expressed as:

$$E = \int P d V \qquad ( 8 )$$

Accordingly, the system may satisfy:

$${E}_{o u t} \leq {E}_{i n} \qquad ( 9 )$$

The passive pressure amplification device inherently trades volumetric flow rate for increased pressure and does not generate energy.

An output volumetric flow rate of the pressure amplification device may decrease as pressure is amplified. In one exemplary approximation, the relationship may be expressed as:

$${\dot{V}}_{o u t} = {\dot{V}}_{i n} ( \frac{{P}_{i n}}{{P}_{o u t}} ) \qquad ( 10 )$$

This relationship reflects mass conservation for a compressible gas under idealized conditions.

A number of pressure stepping stages may be selected based on a desired total pressure ratio R. In one exemplary approximation, the number of stages N may be expressed as:

$$N = \frac{ln ( R )}{ln ( \frac{{V}_{i}}{{V}_{i + 1}} )} \qquad ( 11 )$$

This relationship enables deterministic selection of stage count during design.

Accordingly, embodiments of the passive pressure amplification device disclosed herein may include a plurality of chambers arranged such that effective chamber volume decreases monotonically in a downstream direction, with pressure-responsive valve elements permitting unidirectional flow only when upstream pressure exceeds a spring-defined threshold, whereby cumulative pressure amplification equals a product of sequential chamber volume ratios. In light of the Priest formula framework, pressure gain achieved by the passive pressure amplification device may be deterministic and predictable, volumetric flow rate may decrease proportionally with pressure increase, and performance characteristics may be defined primarily by stage count and chamber geometry. Springs may provide stability and sequencing without contributing compression energy, and the system may be scalable, compact, and passive.

In view of the above framework, an exemplary method of designing a passive pressure amplification device may be disclosed. The method may include determining a desired outlet pressure or desired overall pressure ratio relative to an inlet pressure for a passive, staged pressure stepping device.

The method may further include selecting a target stage pressure ratio or, alternatively, selecting a target effective volume ratio between adjacent chambers. In such embodiments, the effective volume ratio may be selected to promote stable operation by selecting the ratio within a bounded range. The effective volume ratio between chambers may satisfy Formula 6, and, in a preferred range, may satisfy Formula 7.

The method may further include determining a number of stages based on the desired overall pressure ratio. The number of stages may be determined according to Formula 11.

The method may further include determining effective chamber volumes for the plurality of stages such that effective chamber volume decreases monotonically in a downstream direction. In such embodiments, effective chamber volume for a stage may be determined as a sum of geometric chamber volume and additional effective volume components such as dead volume and compliance volume. Effective chamber volume may be expressed as Formula 3.

The method may further include determining a predicted pressure at each stage based on the selected effective chamber volumes. The pressure of a downstream chamber following transfer from an upstream chamber may be expressed according to Formula 1, and an output pressure of the passive pressure amplification device may be expressed as Formula 2. These relationships may be used as first-pass approximations for selecting chamber volumes and stage count to achieve a target outlet pressure.

The method may further include selecting, for each stage, a pressure-responsive valve element configured to permit unidirectional flow between adjacent chambers. The method may further include selecting a valve activation threshold for each stage by selecting a spring preload force and an effective valve seat area such that each valve opens only after an upstream pressure exceeds a predetermined threshold. A valve activation condition for a stage may be expressed according to Formula 4, and, where exposed areas are selected to be approximately equal, may be approximated as Formula 5. The method may further include selecting spring preload forces across stages to enforce sequential activation and to reduce likelihood of simultaneous opening of multiple stages under normal operating conditions.

The foregoing description and accompanying figures illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

What is claimed is:

1. A passive pressure amplification device, comprising:
a main body having an internal chamber defined therein, the internal chamber extending along a longitudinal axis from an upstream end to a downstream end, the internal chamber being in communication with at least one environment external to the main body at the upstream end and at the downstream end;
at least one step defined in the internal chamber, a diameter of the internal chamber decreasing at the step, the step subdividing the internal chamber into at least two subchambers, a downstream subchamber having an effective volume less than an effective volume of an immediately upstream subchamber;
at least one valve body disposed at the at least one step and separating the two respective subchambers, the valve body having a bore defined therethrough connecting the two respective subchambers; and
at least one check valve arrangement, the check valve arrangement cooperating with a respective valve body, the check valve arrangement being configured to permit gas flow from the upstream subchamber to the downstream subchamber when pressure within the upstream subchamber exceeds a predetermined threshold.

2. The passive pressure amplification device of claim 1, wherein the predetermined threshold includes a biasing force of the check valve arrangement.

3. The passive pressure amplification device of claim 1, wherein a portion of the check valve arrangement is received within the bore of the valve body so as to impede gas flow through the bore until pressure of the gas within the upstream subchamber exceeds the predetermined threshold.

4. The passive pressure amplification device of claim 1, further comprising:
a plurality of steps defined in the internal chamber, the diameter of the internal chamber decreasing at each step of the plurality of steps, each step subdividing the internal chamber into two adjacent subchambers, a downstream subchamber of the two adjacent subchambers having an effective volume less than an effective volume of an immediately upstream subchamber of the two adjacent subchambers;
a plurality of valve bodies, each valve body disposed at each step and separating the two associated adjacent subchambers, each valve body having a bore defined therethrough connecting the two adjacent subchambers;
a plurality of check valve arrangements, each check valve arrangement cooperating with the respective valve body, each check valve arrangement being configured to permit gas flow from the respective upstream subchamber to the respective downstream subchamber when pressure within the upstream subchamber exceeds a predetermined threshold.

5. The passive pressure amplification device of claim 4, wherein the predetermined threshold includes a biasing force of the check valve arrangement.

6. The passive pressure amplification device of claim 4, wherein a portion of each check valve arrangement is received within the bore of the respective valve body so as to impede gas flow through the bore until pressure of the gas within the upstream subchamber exceeds the predetermined threshold.

7. The passive pressure amplification device of claim 4, wherein the effective volume of the subchambers decreases monotonically in the downstream direction.

8. The passive pressure amplification device of claim 4, wherein the internal chamber, the plurality of valve bodies, and the plurality of check valve arrangements are arranged coaxially along the longitudinal axis.

9. A passive pressure amplification device, comprising:
a main body having an internal chamber defined therein, the internal chamber extending along a longitudinal axis from an upstream end to a downstream end, the internal chamber being in communication with at least one environment external to the main body at the upstream end and at the downstream end; and
at least one pressure stepping stage disposed within the internal chamber, the pressure stepping stage comprising:
an upstream subchamber and a downstream subchamber, the downstream subchamber having an effective volume less than an effective volume of the upstream subchamber;
a valve body disposed between and separating the upstream subchamber and the downstream subchamber, the valve body having a passage defined therethrough connecting the upstream subchamber and downstream subchamber; and
a pressure-responsive valve element cooperating with the valve body and configured to permit gas flow from the upstream subchamber to the downstream subchamber when a pressure within the upstream subchamber exceeds a predetermined threshold.

10. The passive pressure amplification device of claim 9, wherein the predetermined threshold includes a biasing force of the valve element.

11. The passive pressure amplification device of claim 9, wherein the passive pressure amplification device comprises a plurality of pressure stepping stages disposed in the internal chamber.

12. The passive pressure amplification device of claim 9, wherein a pressure within the downstream subchamber, following transfer of gas from the upstream subchamber, is related to the pressure within the upstream subchamber by a ratio of the effective volume of the upstream subchamber to the effective volume of the downstream subchamber.

13. The passive pressure amplification device of claim 11, wherein, for each pressure stepping stage, a pressure within the downstream subchamber, following transfer of gas from the upstream subchamber, is related to the pressure within the upstream subchamber by a ratio of the effective volume of the upstream subchamber to the effective volume of the downstream subchamber.

14. The passive pressure amplification device of claim 11, wherein cumulative pressure amplification across the plurality of pressure stepping stages corresponds to a product of effective volume ratios associated with the plurality of pressure stepping stages.

15. The passive pressure amplification device of claim 11, wherein a predetermined threshold of a valve element of a downstream pressure stepping stage is greater than a predetermined threshold of a valve element of an upstream pressure stepping stage.

16. A method of designing a passive pressure amplification device, comprising:
determining a desired outlet pressure relative to an inlet pressure for the passive pressure amplification device;
selecting at least one pressure stepping stage, the pressure stepping stage comprising an upstream subchamber and a downstream subchamber separated by a valve body and a pressure-responsive valve element;
selecting a target stage pressure ratio for the pressure stepping stage or an effective volume ratio between the upstream subchamber and the downstream subchamber;
determining an effective upstream subchamber volume and an effective downstream subchamber volume such that the downstream subchamber volume is less than the upstream subchamber volume;
configuring the valve body and the pressure-responsive valve element such that gas is transferred from the upstream subchamber to the downstream subchamber only when pressure within the upstream subchamber exceeds a predetermined threshold.

17. The method of claim 16, wherein the target stage pressure ratio is selected within a bounded range.

18. The method of claim 16, further comprising selecting a plurality of pressure stepping stages arranged in series such that cumulative pressure amplification corresponds to a product of effective volume ratios associated with the plurality of pressure stepping stages.

19. The method of claim 18, further comprising:
determining effective chamber volumes for the plurality of pressure stepping stages such that effective chamber volume decreases monotonically in a downstream direction; and
determining a predicted pressure at each stage based on the determined effective chamber volumes.

20. The method of claim 18, further comprising selecting, for each pressure stepping stage, a predetermined threshold for the corresponding pressure-responsive valve element, such that unidirectional downstream flow is enforced between pressure stepping stages.
